(19) United States
(12) Patent Application Publication
(10) Pub. No.: US 2023/0352900 A1
(43) Pub. Date: Nov. 2, 2023

(54) LASER APPARATUS AND METHOD OF MANUFACTURING ELECTRONIC DEVICE

(71) Applicant: Gigaphoton Inc., Tochigi (JP)

(72) Inventors: Koichi FUJII, Oyama-shi (JP); Osamu WAKABAYASHI, Oyama-shi (JP)

(73) Assignee: Gigaphoton Inc., Tochigi (JP)

(21) Appl. No.: 18/348,518

(22) Filed: Jul. 7, 2023

Related U.S. Application Data
(63) Continuation of application No. PCT/JP2021/006904, filed on Feb. 24, 2021.

(51) Int. Cl. H01S 3/1055; G03F 7/20; H01S 3/139

(52) U.S. Cl. CPC H01S 3/1055; G03F 7/20; H01S 3/139

(57) ABSTRACT

A laser apparatus includes a grating system; an actuator system configured to adjust a first incident angle on the grating system and a second incident angle on the grating system, the first incident angle being an angle of a first part of an optical beam incident on the grating system, the second incident angle being an angle of a second part of the optical beam incident on the grating system; and a processor configured to control the actuator system to periodically vary the first and second incident angles so that the first and second incident angles are different from each other in at least one of phase and variation range.

### CROSS-REFERENCE TO RELATED APPLICATIONS

The present application is a continuation application of International Application No. PCT/JP2021/006904, filed on Feb. 24, 2021, the entire contents of which are hereby incorporated by reference.

### BACKGROUND

### 1. Technical Field

The present disclosure relates to a laser apparatus and a method of manufacturing an electronic device.

### 2. Related Art

Recently, in a semiconductor exposure apparatus, resolving power improvement has been requested along with miniaturization and high integration of a semiconductor integrated circuit. Thus, the wavelength of light discharged from an exposure light source has been shortened. Examples of a gas laser apparatus for exposure include a KrF excimer laser apparatus configured to output a laser beam having a wavelength of approximately 248 nm and an ArF excimer laser apparatus configured to output a laser beam having a wavelength of approximately 193 nm.

The KrF excimer laser apparatus and the ArF excimer laser apparatus have a wide spectrum line width of 350 pm to 400 pm for spontaneous oscillation light. Thus, chromatic aberration occurs in some cases when a projection lens is made of a material that transmits ultraviolet such as KrF and ArF laser beams. This can lead to resolving power decrease. Thus, the spectrum line width of a laser beam output from the gas laser apparatus needs to be narrowed so that chromatic aberration becomes negligible. To narrow the spectrum line width, a line narrowing module (LNM) including a line narrowing element (for example, etalon or grating) is provided in a laser resonator of the gas laser apparatus in some cases. In the following, a gas laser apparatus that achieves narrowing of the spectrum line width is referred to as a line narrowed gas laser apparatus.

### LIST OF DOCUMENTS

### Patent Documents

Patent Document 1: US Published Patent Application No. 2005/0083983

### SUMMARY

A laser apparatus according to an aspect of the present disclosure includes a grating system; an actuator system configured to adjust a first incident angle on the grating system and a second incident angle on the grating system, the first incident angle being an angle of a first part of an optical beam incident on the grating system, the second incident angle being an angle of a second part of the optical beam incident on the grating system; and a processor configured to control the actuator system to periodically vary the first and second incident angles so that the first and second incident angles are different from each other in at least one of phase and variation range.

A method of manufacturing an electronic device according to an aspect of the present disclosure includes generating a laser beam with a laser apparatus, the laser apparatus including a grating system, an actuator system configured to adjust a first incident angle on the grating system and a second incident angle on the grating system, the first incident angle being an angle of a first part of an optical beam incident on the grating system, the second incident angle being an angle of a second part of the optical beam incident on the grating system, and a processor configured to control the actuator system to periodically vary the first and second incident angles so that the first and second incident angles are different from each other in at least one of phase and variation range; outputting the laser beam to an exposure apparatus; and exposing a photosensitive substrate to the laser beam in the exposure apparatus to manufacture the electronic device.

### BRIEF DESCRIPTION OF THE DRAWINGS

Embodiments of the present disclosure will be described below merely as examples with reference to the accompanying drawings.

FIG. 1 schematically illustrates the configuration of an exposure system in a comparative example.

FIG. 2 schematically illustrates the configuration of a laser apparatus in the comparative example.

FIG. 3 illustrates a situation in which the position of a scanning field of an irradiation target object changes relative to the position of a pulse laser beam.

FIG. 4 illustrates a situation in which the position of the scanning field of the irradiation target object changes relative to the position of the pulse laser beam.

FIG. 5 illustrates a situation in which the position of the scanning field of the irradiation target object changes relative to the position of the pulse laser beam.

FIG. 6 is a graph illustrating exemplary drive voltage of a rotation stage in the comparative example.

FIG. 7 illustrates an ideal integration spectrum waveform in one period when the drive voltage illustrated in FIG. 6 is applied to the rotation stage.

FIG. 8 is a graph illustrating a first example of change in the incident angle of an optical beam incident on a grating in the comparative example.

FIG. 9 illustrates an integration spectrum waveform when the incident angle of an optical beam incident on the grating has changed as illustrated in FIG. 8.

FIG. 10 is a graph illustrating a second example of change in the incident angle of an optical beam incident on the grating in the comparative example.

FIG. 11 illustrates an integration spectrum waveform when the incident angle of an optical beam incident on the grating has changed as illustrated in FIG. 10.

FIG. 12 schematically illustrates the configuration of a laser apparatus according to a first embodiment.

FIG. 13 is a perspective view of first and second mirrors.

FIG. 14 is a graph illustrating an example of drive voltages applied to rotation stages in the first embodiment.

FIG. 15 illustrates an integration spectrum waveform in half period when the drive voltages illustrated in FIG. 14 are applied to the rotation stages.

FIG. 16 is a graph illustrating a modification of the drive voltages applied to the rotation stages in the first embodiment.

FIG. 17 is a flowchart illustrating processing of setting start voltage and end voltage in the first embodiment.

FIG. 18 is a graph illustrating exemplary drive voltages applied to the rotation stages in a second embodiment.

FIG. 19 is a graph illustrating exemplary drive voltages applied to the rotation stages in the second embodiment.

FIG. 20 is a graph illustrating exemplary drive voltages applied to the rotation stages in the second embodiment.

FIG. 21 is a graph illustrating an example of a first incident angle of a first part and a second incident angle of a second part that are incident on the grating in the second embodiment.

FIG. 22 is a flowchart illustrating processing of setting first start voltage, first end voltage, second start voltage, and second end voltage in the second embodiment.

FIG. 23 is a graph illustrating a modification of the first and second incident angles in the second embodiment.

FIG. 24 illustrates an example of an integration spectrum waveform in one period in the second embodiment.

FIG. 25 illustrates a modification of the integration spectrum waveform in one period in the second embodiment.

FIG. 26 schematically illustrates the configuration of a laser apparatus according to a third embodiment.

FIG. 27 is a perspective view of a prism.

FIG. 28 is a side view of the prism.

FIG. 29 schematically illustrates the configuration of a laser apparatus according to a fourth embodiment.

FIG. 30 is a perspective view of first and second gratings.

FIG. 31 is a graph illustrating an example of drive voltages applied to rotation stages in a fifth embodiment.

FIG. 32 illustrates an integration spectrum waveform in half period when the drive voltages illustrated in FIG. 31 are applied to the rotation stages.

### DESCRIPTION OF EMBODIMENTS

### Contents

1. Comparative example
   1.1 Exposure system
      1.1.1 Configuration of exposure apparatus 200
      1.1.2 Operation
   1.2 Laser apparatus 100
      1.2.1 Configuration
      1.2.2 Operation
   1.3 Line narrowing module 14
      1.3.1 Configuration
      1.3.2 Operation
   1.4 Number N of irradiation pulses
   1.5 Exemplary periodic wavelength change
   1.6 Problem of comparative example
2. Laser apparatus 100a with mutually different phases of first and second incident angles α1 and α2
   2.1 Configuration
   2.2 Operation
   2.3 Effect
3. Laser apparatus 100a with mutually different variation ranges of first and second incident angles α1 and α2
   3.1 Configuration and operation
   3.2 Effect
4. Laser apparatus 100c that adjusts first and second incident angles α1 and α2 by adjusting rotation angles θ1 and θ2 of prisms 44 and 45
   4.1 Configuration and operation
   4.2 Effect
5. Laser apparatus 100d that adjusts first and second incident angles α1 and α2 by adjusting rotation angles θ1 and θ2 of first and second gratings 51 and 52
   5.1 Configuration and operation
   5.2 Effect
6. Laser apparatus 100a that varies first and second incident angles α1 and α2 in sinusoidal shape
   6.1 Configuration and operation
   6.2 Effect
7. Other

Embodiments of the present disclosure will be described below in detail with reference to the accompanying drawings. The embodiments described below are examples of the present disclosure, and do not limit the contents of the present disclosure. Not all configurations and operations described in each embodiment are necessarily essential as configurations and operations of the present disclosure. Components identical to each other are denoted by an identical reference sign, and duplicate description thereof will be omitted.

### 1. Comparative Example

### 1.1 Exposure System

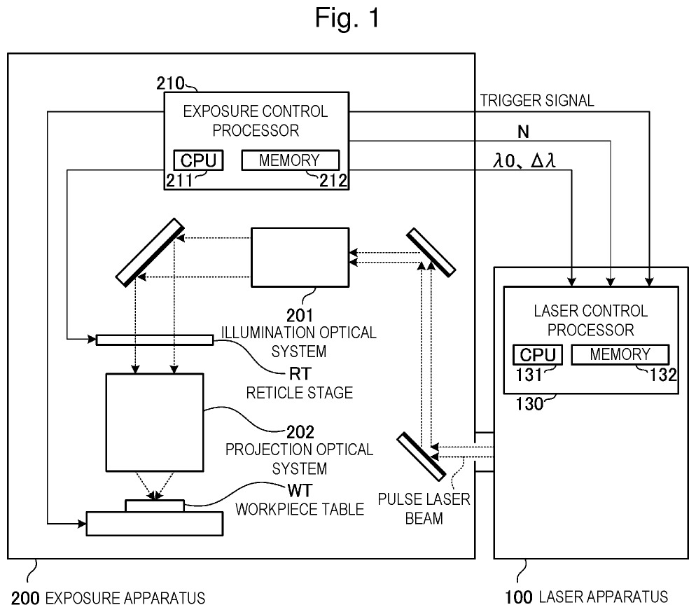

FIG. 1 schematically illustrates the configuration of an exposure system in a comparative example. The comparative example of the present disclosure is an example that the applicant recognizes as known only by the applicant, but is not a publicly known example that is recognized by the applicant.

The exposure system includes a laser apparatus 100 and an exposure apparatus 200. In FIG. 1, the laser apparatus 100 is simplified.

The laser apparatus 100 generates a pulse laser beam and outputs the pulse laser beam toward the exposure apparatus 200. The laser apparatus 100 includes a laser control processor 130. The laser control processor 130 is a processing device including a memory 132 in which a control program is stored and a central processing unit (CPU) 131 configured to execute the control program. The laser control processor 130 is specially configured or programmed to execute various kinds of processing included in the present disclosure.

### 1.1.1 Configuration of Exposure Apparatus 200

As illustrated in FIG. 1, the exposure apparatus 200 includes an illumination optical system 201, a projection optical system 202, and an exposure control processor 210.

The illumination optical system 201 illuminates the reticle pattern of a non-illustrated reticle disposed on a reticle stage RT with the pulse laser beam incident from the laser apparatus 100.

The pulse laser beam having transmitted through the reticle is imaged on a non-illustrated workpiece disposed on a workpiece table WT by reduced projection through the projection optical system 202. The workpiece is a photosensitive substrate such as a semiconductor wafer on which a resist film is applied.

The exposure control processor 210 is a processing device including a memory 212 in which a control program is stored and a CPU 211 configured to execute the control program. The exposure control processor 210 is specially configured or programmed to execute various kinds of processing included in the present disclosure.

### 1.1.2 Operation

The exposure control processor 210 transmits data and a trigger signal to the laser control processor 130, the data including a number N of irradiation pulses, an integration spectrum central wavelength λ0, and a wavelength range Δλ. The laser control processor 130 controls the laser apparatus 100 in accordance with the data and signal received from the exposure control processor 210.

The exposure control processor 210 translates the reticle stage RT and the workpiece table WT in directions opposite to each other in synchronization. Accordingly, the workpiece is exposed to the pulse laser beam reflected by the reticle pattern.

Through such an exposure process, the reticle pattern is transferred to the semiconductor wafer. Thereafter, an electronic device can be manufactured through a plurality of processes.

### 1.2 Laser Apparatus 100

### 1.2.1 Configuration

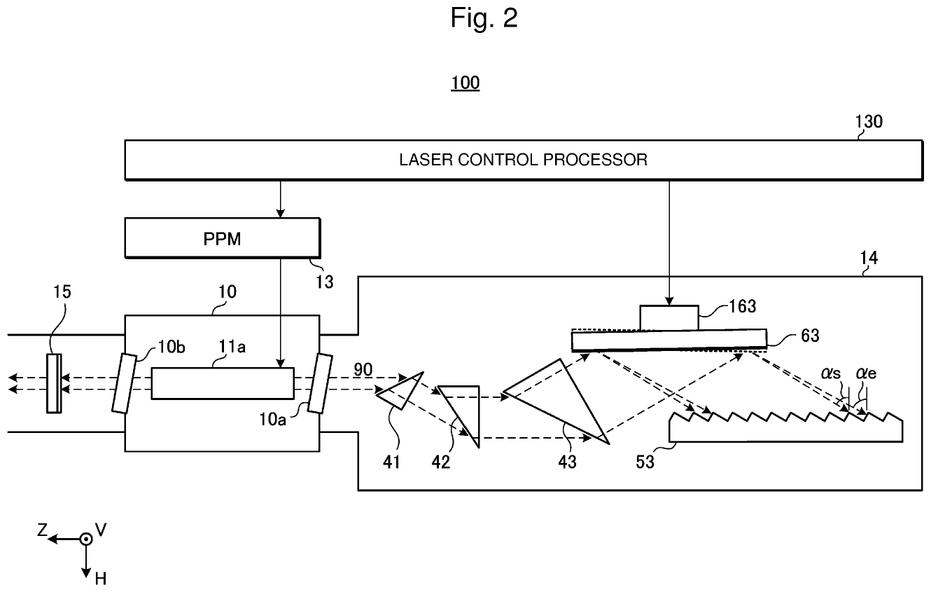

FIG. 2 schematically illustrates the configuration of the laser apparatus 100 in the comparative example. A V axis, an H axis, and a Z axis that are orthogonal to each other are illustrated in FIG. 2. FIG. 2 illustrates the laser apparatus 100 viewed in the negative V axial direction.

The laser apparatus 100 includes a laser chamber 10, a pulse power module (PPM) 13, a line narrowing module 14, an output coupling mirror 15 in addition to the laser control processor 130. The line narrowing module 14 and the output coupling mirror 15 constitute an optical resonator.

The laser chamber 10 is disposed on the optical path of the optical resonator. The laser chamber 10 is provided with windows 10a and 10b.

A discharge electrode 11a and a non-illustrated discharge electrode paired with the discharge electrode 11a are disposed inside the laser chamber 10. The non-illustrated discharge electrode is positioned to overlap the discharge electrode 11a in the V axial direction. Laser gas including, for example, argon gas or krypton gas as rare gas, fluorine gas as halogen gas, and neon gas as buffer gas is encapsulated in the laser chamber 10.

The pulse power module 13 includes a non-illustrated switch and is connected to a non-illustrated charger.

The line narrowing module 14 includes prisms 41 to 43, a mirror 63, and a grating 53. The line narrowing module 14 will be described later in detail.

The output coupling mirror 15 is a partially reflective mirror.

### 1.2.2 Operation

The laser control processor 130 receives, from the exposure control processor 210, data including the number N of irradiation pulses, the integration spectrum central wavelength λ0, and the wavelength range Δλ. The data may be received from a non-illustrated lithography control device different from the exposure apparatus 200. The lithography control device may control a plurality of exposure apparatuses 200.

The laser control processor 130 calculates a start wavelength λs and an end wavelength λe based on the integration spectrum central wavelength λ0 and the wavelength range Δλ. The start wavelength λs is calculated by subtracting half of the wavelength range Δλ from the integration spectrum central wavelength λ0. The end wavelength λe is calculated by adding half of the wavelength range Δλ to the integration spectrum central wavelength λ0. The laser control processor 130 transmits a control signal to the line narrowing module 14 based on the start wavelength λs and the end wavelength λe.

The laser control processor 130 receives a trigger signal from the exposure control processor 210. The laser control processor 130 transmits an oscillation trigger signal based on the trigger signal to the pulse power module 13. The switch included in the pulse power module 13 is turned on upon reception of the oscillation trigger signal from the laser control processor 130. When the switch is turned on, the pulse power module 13 generates high voltage in pulses from electric energy charged in the charger and applies the high voltage to the discharge electrode 11a.

When the high voltage is applied to the discharge electrode 11a, discharging occurs inside the laser chamber 10. The laser gas inside the laser chamber 10 is excited by energy of the discharging and transitions to a higher energy level. Thereafter, when transitioning to a lower energy level, the excited laser gas discharges light of a wavelength in accordance with the difference between the energy levels.

The light generated inside the laser chamber 10 is output to the outside of the laser chamber 10 through the windows 10a and 10b. The light output through the window 10a is incident as an optical beam 90 on the line narrowing module 14. Light near a desired wavelength in the optical beam 90 incident on the line narrowing module 14 is returned from the line narrowing module 14 to the laser chamber 10.

The output coupling mirror 15 transmits and outputs part of the light output through the window 10b and reflects another part thereof to the laser chamber 10.

In this manner, light output from the laser chamber 10 reciprocates between the line narrowing module 14 and the output coupling mirror 15. The light is amplified each time the light passes through a discharge space inside the laser chamber 10. In addition, the light is narrowed each time the light is returned by the line narrowing module 14, and becomes light with an abrupt wavelength distribution having a pulse spectrum central wavelength at part of a selection wavelength range of the line narrowing module 14. In this manner, light subjected to laser oscillation and line narrowing is output as a pulse laser beam from the output coupling mirror 15.

The pulse laser beam output from the laser apparatus 100 is incident on the exposure apparatus 200.

### 1.3 Line Narrowing Module 14

### 1.3.1 Configuration

The prisms 41, 42, and 43 are disposed in the stated order on the optical path of the optical beam 90 output through the window 10a. The prisms 41 to 43 are disposed such that surfaces of the prisms 41 to 43 to and from which the optical beam 90 is input and output are parallel to the V axis, and are each supported by a non-illustrated holder.

The mirror 63 is disposed on the optical path of the optical beam 90 having transmitted through the prisms 41 to 43. The mirror 63 is disposed such that a surface thereof by which the optical beam 90 is reflected is parallel to the V axis, and is rotatable about an axis parallel to the V axis by a rotation stage 163. The rotation stage 163 is, for example, a highly responsive rotation stage rotated by a piezoelectric element.

The grating 53 is disposed on the optical path of the optical beam 90 reflected by the mirror 63. The direction of grooves of the grating 53 is parallel to the V axis.

The grating 53 is supported by a non-illustrated holder.

### 1.3.2 Operation

Through each of the prisms 41 to 43, the traveling direction of the optical beam 90 output through the window 10a is changed in a plane parallel to an HZ plane that is orthogonal to the V axis, and the beam width thereof is expanded in the plane parallel to the HZ plane.

The optical beam 90 having transmitted through the prisms 41 to 43 is reflected by the mirror 63 and incident on the grating 53.

The optical beam 90 incident on the grating 53 is reflected by the grooves of the grating 53 and diffracted in a direction in accordance with the wavelength of the light. The grating 53 is disposed in Littrow arrangement such that an incident angle α of the optical beam 90 incident on the grating 53 from the mirror 63 matches the diffraction angle of diffracted light at a desired wavelength.

The mirror 63 and the prisms 41 to 43 reduce the beam width of light returned from the grating 53 in a plane parallel to the HZ plane and return the light into the laser chamber 10 through the window 10a.

The laser control processor 130 controls the rotation stage 163 through a non-illustrated driver. A rotation angle θ of the mirror 63 changes in accordance with drive voltage V applied from the driver to the rotation stage 163. The incident angle α of the optical beam 90 incident on the grating 53 changes between a start incident angle αs and an end incident angle αe in accordance with the rotation angle θ, and accordingly, a wavelength λ selected by the line narrowing module 14 changes.

The relation between the rotation angle θ and the drive voltage V is expressed by a relational expression θ=g(V), and for example, the rotation angle θ increase as the drive voltage V increases. The relation between the wavelength λ and the rotation angle θ is expressed by a relational expression λ=f(0), and for example, the incident angle α and the wavelength λ increase as the rotation angle θ increases.

The laser control processor 130 controls the rotation stage 163 at each pulse based on the integration spectrum central wavelength λ0 and the wavelength range Δλ received from the exposure control processor 210 such that the posture of the mirror 63 periodically changes for each of a plurality of pulses. Accordingly, the pulse spectrum central wavelength changes at multiple stages in the wavelength range Δλ centered at the integration spectrum central wavelength λ0 and periodically changes for each of a plurality of pulses. In this manner, the laser apparatus 100 can perform multiple wavelength oscillation by changing the pulse spectrum central wavelength over a plurality of pulses.

A focal length in the exposure apparatus 200 (refer to FIG. 1) depends on the wavelength of a pulse laser beam. A pulse laser beam subjected to the multiple wavelength oscillation and incident on the exposure apparatus 200 can form an image at a large number of positions different from one another in the direction of the optical path axis of the pulse laser beam, and thus a focal point depth can be increased in effect. For example, when a resist film having a large film thickness is exposed, imaging performance in the thickness direction of the resist film can be maintained.

### 1.4 Number N of Irradiation Pulses

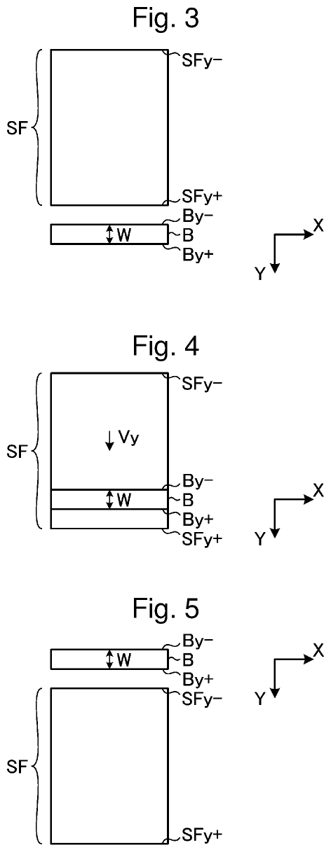

FIG. 3 to 5 illustrate a situation in which the position of a scanning field SF of an irradiation target object changes relative to the position of a pulse laser beam. The irradiation target object is, for example, a semiconductor wafer. The scanning field SF of the semiconductor wafer corresponds to, for example, a region in which some of a large number of semiconductor chips to be formed on the semiconductor wafer are formed. A resist film is applied in the scanning field SF. The width of the scanning field SF in the X axial direction is equal to the width of a beam section B of the pulse laser beam in the X axial direction at the position of the irradiation target object. The width of the scanning field SF in the Y axial direction is larger than a width W of the beam section B of the pulse laser beam in the Y axial direction at the position of the irradiation target object.

Exposure of the scanning field SF to the pulse laser beam is performed in order through procedures illustrated in FIGS. 3, 4, and 5. First, as illustrated in FIG. 3, the workpiece table WT is positioned such that an end SFy+ of the scanning field SF in the positive Y axial direction is separately positioned by a predetermined distance in the negative Y axial direction relative to the position of an end By− of the beam section B in the negative Y axial direction. Then, the workpiece table WT is accelerated in the positive Y axial direction so that speed Vy is reached before the end SFy+ of the scanning field SF in the positive Y axial direction matches the position of the end By− of the beam section B in the negative Y axial direction. As illustrated in FIG. 4, the workpiece table WT is moved with uniform linear motion of the position of the scanning field SF at the speed Vy relative to the position of the beam section B. As illustrated in FIG. 5, the exposure of the scanning field SF ends when the workpiece table WT is moved such that an end SFy− of the scanning field SF in the negative Y axial direction passes by the position of an end By+ of the beam section B in the positive Y axial direction. In this manner, the exposure is performed while the scanning field SF is moved relative to the position of the beam section B.

A required time T for the scanning field SF to move a distance equivalent to the width W of the beam section B of the pulse laser beam at the speed Vy is calculated as follows.

T=W/Vy Expression 1

The number N of irradiation pulses of the pulse laser beam with which an optional place in the scanning field SF is irradiated is equal to the number of pulses of the pulse laser beam generated in the required time T, and is calculated as follows.

N=F·T Expression 2

where F represents the repetition frequency of the pulse laser beam.

The number N of irradiation pulses is also referred to as an N slit pulse number.

### 1.5 Exemplary Periodic Wavelength Change

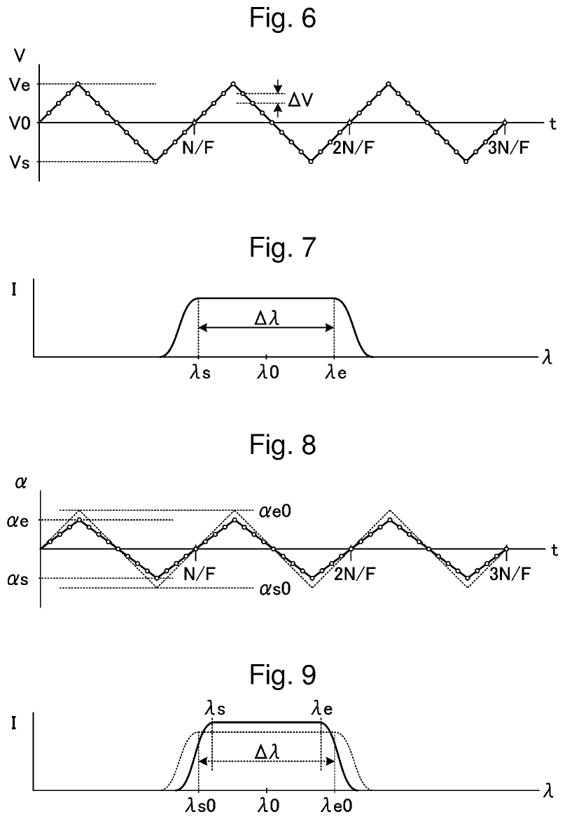

FIG. 6 is a graph illustrating exemplary drive voltage V of the rotation stage 163 in the comparative example. In FIG. 6, the horizontal axis represents time t, and the vertical axis represents the drive voltage V.

In the example illustrated in FIG. 6, the drive voltage V periodically changes between start voltage Vs and end voltage Ve. The start voltage Vs is drive voltage corresponding to the start wavelength λs, and the end voltage Ve is drive voltage corresponding to the end wavelength λe. Each small circle illustrated in FIG. 6 represents an output timing of the pulse laser beam and the drive voltage V at the timing. The drive voltage V changes by a constant voltage shift amount ΔV at each pulse. The drive voltage V varies in a variation period that is a time N/F obtained by multiplying a repetition period 1/F of the pulse laser beam by the number N of irradiation pulses. According to Expression 2 above, the time N/F is equal to the required time T. When the drive voltage V varies in the variation period equal to the required time T, a constant movement integration spectrum waveform is obtained at any part of the scanning field SF of the irradiation target object.

FIG. 7 illustrates an ideal integration spectrum waveform in one period when the drive voltage V illustrated in FIG. 6 is applied to the rotation stage 163. In FIG. 7, the horizontal axis represents the wavelength λ, and the vertical axis represents light intensity I. When the drive voltage V changes at multiple stages between the start voltage Vs and the end voltage Ve as illustrated in FIG. 6, the integration spectrum waveform illustrated in FIG. 7 is a flat-top spectrum waveform with the light intensity I that is substantially uniform between the start wavelength λs and the end wavelength λe.

The variation of the drive voltage V is not limited to a triangular wave shape illustrated in FIG. 6 but may be in a sawtooth wave shape.

### 1.6 Problem of Comparative Example

FIG. 8 is a graph illustrating a first example of change in the incident angle α of the optical beam 90 incident on the grating 53 in the comparative example. The incident angle α of the optical beam 90 incident on the grating 53 changes in accordance with the drive voltage V applied to the rotation stage 163. However, when the angular velocity of the mirror 63 due to the rotation stage 163 is insufficient, the incident angle α potentially does not reach an ideal start incident angle αs0 corresponding to the start voltage Vs nor an ideal end incident angle αe0 corresponding to the end voltage Ve. For example, the incident angle α potentially changes between the start incident angle αs and the end incident angle αe.

FIG. 9 illustrates the integration spectrum waveform when the incident angle α of the optical beam 90 incident on the grating 53 has changed as illustrated in FIG. 8. When the angular velocity of the mirror 63 is insufficient, the pulse spectrum central wavelength does not reach an ideal start wavelength λs0 nor an ideal end wavelength λe0 but changes between the start wavelength λs and the end wavelength λe, and thus the wavelength range Δλ requested by the exposure apparatus 200 potentially cannot be achieved.

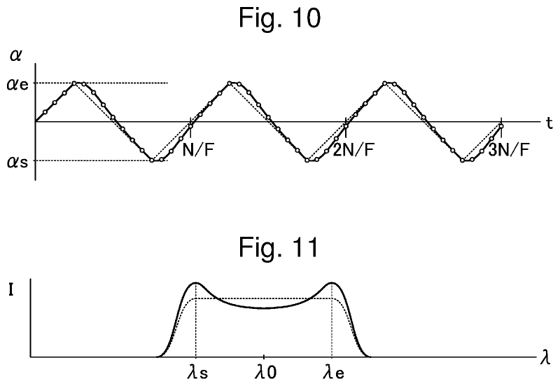

FIG. 10 is a graph illustrating a second example of change in the incident angle α of the optical beam 90 incident on the grating 53 in the comparative example. When the angular acceleration of the mirror 63 due to the rotation stage 163 is insufficient, rotation of the mirror 63 potentially retards right after rotational direction switching.

FIG. 11 illustrates the integration spectrum waveform when the incident angle α of the optical beam 90 incident on the grating 53 has changed as illustrated in FIG. 10. When the angular acceleration of the mirror 63 is insufficient, the pulse spectrum central wavelength is potentially unevenly positioned near the start wavelength λs and the end wavelength λe. As a result, the light intensity I of the integration spectrum waveform is higher near the start wavelength λs and the end wavelength λe, and the integration spectrum waveform in an ideal flat-top shape is potentially not obtained.

In embodiments described below, a first incident angle α1 of a first part 91 and a second incident angle α2 of a second part 92 of the optical beam 90 incident on the grating 53 are varied such that the phases or variation ranges of the incident angles α1 and α2 are different from each other. Accordingly, the integration spectrum waveform in a flat-top shape having a wide wavelength range Δλ can be achieved.

### 2. Laser Apparatus 100a with Mutually Different Phases of First and Second Incident Angles α1 and α2

### 2.1 Configuration

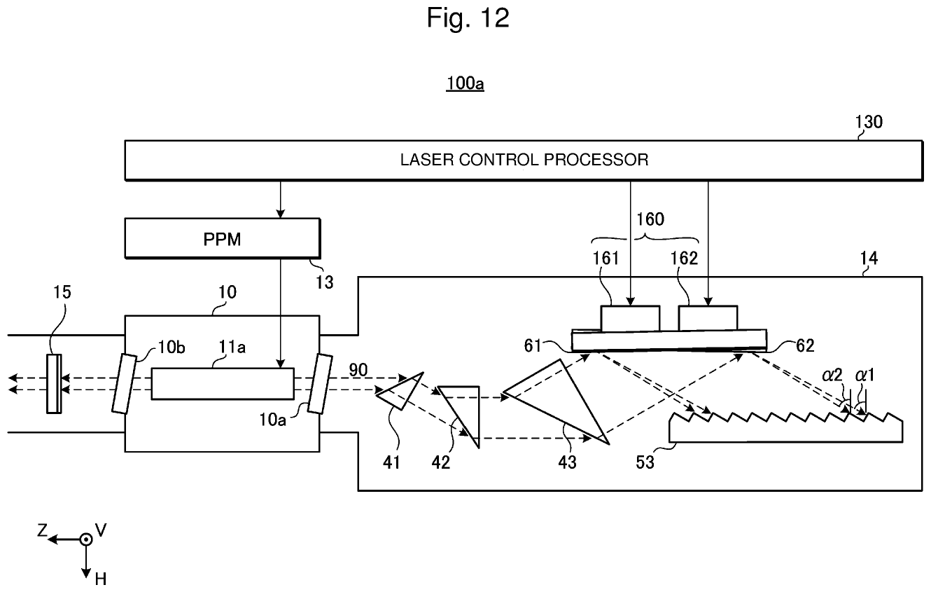

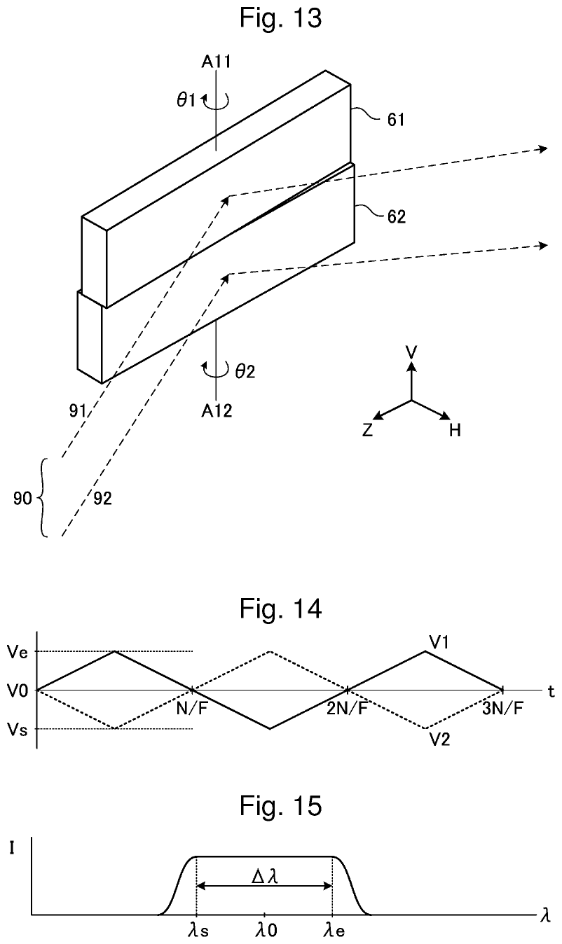

FIG. 12 schematically illustrates the configuration of a laser apparatus 100a according to a first embodiment. FIG. 12 corresponds to a view of the laser apparatus 100a in the same direction as in FIG. 2 in the comparative example. The laser apparatus 100a includes first and second mirrors 61 and 62 in place of the mirror 63 illustrated in FIG. 2. FIG. 13 is a perspective view of the first and second mirrors 61 and 62.

The first and second mirrors 61 and 62 are disposed side by side in a direction parallel to the V axis. The first and second mirrors 61 and 62 are disposed such that respective surfaces thereof by which the optical beam 90 is reflected are parallel to the V axis. The first and second mirrors 61 and 62 are independently rotatable about axes A11 and A12 parallel to the V axis by rotation stages 161 and 162, respectively. The first and second mirrors 61 and 62 are preferably disposed in proximity at an interval equal to or smaller than 0.5 mm, for example, such that the first and second mirrors 61 and 62 do not collide with each other and an energy loss is reduced. The rotation stages 161 and 162 constituting an actuator system 160 correspond to first and second actuators, respectively.

The first and second mirrors 61 and 62 are disposed such that the optical beam 90 output from the laser chamber 10 and having transmitted through the prisms 41 to 43 is incident across the first and second mirrors 61 and 62. In the optical beam 90, a part incident on the first mirror 61 is the first part 91 and a part incident on the second mirror 62 is the second part 92. FIG. 13 illustrates the central axes of the optical paths of the first and second parts 91 and 92. The first and second parts 91 and 92 are reflected by the first and second mirrors 61 and 62, respectively, and incident on the grating 53. The grating 53 is an example of a grating system in the present disclosure.

In accordance with drive voltages V1 and V2 applied to the rotation stages 161 and 162, rotation angles θ1 and θ2 of the first and second mirrors 61 and 62 change, respectively, and the directions of reflection of the first and second parts 91 and 92 by the first and second mirrors 61 and 62 change, respectively. Accordingly, the first incident angle α1 of the first part 91 and the second incident angle α2 of the second part 92 that are incident on the grating 53 are adjusted. In the present disclosure, the drive voltages V1 and V2 are also collectively referred to as the drive voltage V, and the rotation angles θ1 and θ2 are also collectively referred to as the rotation angle θ.

### 2.2 Operation

FIG. 14 is a graph illustrating an example of the drive voltages V1 and V2 applied to the rotation stages 161 and 162 in the first embodiment. In FIG. 14, the horizontal axis represents time t, and the vertical axis represents the drive voltages V1 and V2. The drive voltages V1 and V2 in the first embodiment have characteristics as follows.
(a) The drive voltages V1 and V2 periodically vary in phases opposite to each other. In other words, the phase difference therebetween is π radian.
(b) The drive voltages V1 and V2 each change between the start voltage Vs and the end voltage Ve. In other words, the variation ranges of the drive voltages V1 and V2 are identical to each other.
(c) The drive voltages V1 and V2 each vary in a variation period equal to a time 2N/F obtained by multiplying the repetition period 1/F of the pulse laser beam by twice of the number N of irradiation pulses.

FIG. 15 illustrates the integration spectrum waveform in the half period N/F when the drive voltages V1 and V2 illustrated in FIG. 14 are applied to the rotation stages 161 and 162, respectively. In FIG. 15, the horizontal axis represents the wavelength λ, and the vertical axis represents the light intensity I. According to the first embodiment, the drive voltages V1 and V2 in phases opposite to each other are applied to the rotation stages 161 and 162 so that the first and second incident angles α1 and α2 vary between the start incident angle αs and the end incident angle αe in phases opposite to each other. Accordingly, the integration spectrum waveform in the half period N/F is a flat-top spectrum waveform having a substantially uniform light intensity I between the start wavelength λs and the end wavelength λe.

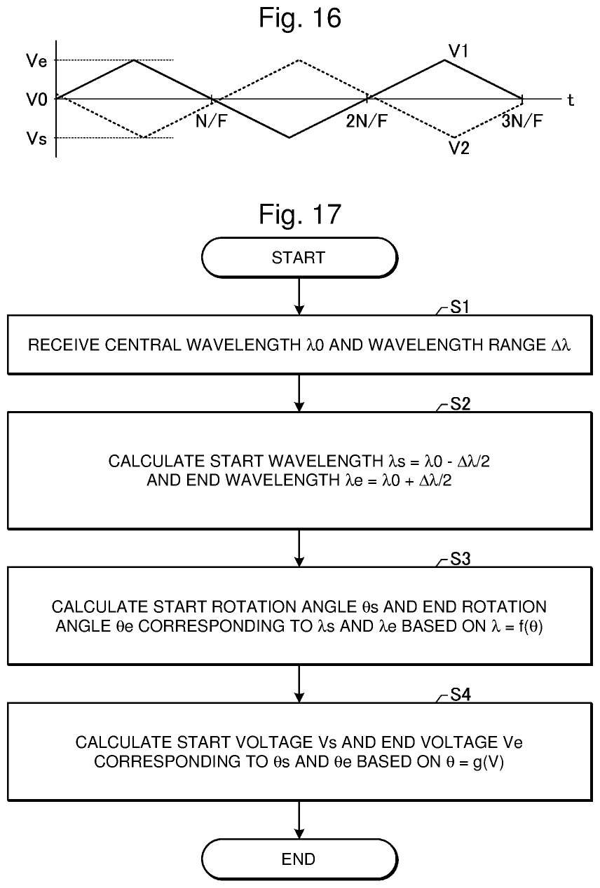

FIG. 16 is a graph illustrating a modification of the drive voltages V1 and V2 applied to the rotation stages 161 and 162 in the first embodiment. In FIG. 16, the horizontal axis represents time t, and the vertical axis represents the drive voltages V1 and V2. The phase difference between the drive voltages V1 and V2 in FIG. 16 is slightly shifted from 7C radian. When the phases are not opposite to each other, the integration spectrum waveform in the half period N/F does not have a constant waveform but can vary. The size of variation of the integration spectrum waveform depends on the phase difference. When the phase difference is 7π/8 radian to 9π/8 radian inclusive, variation of the integration spectrum waveform is small and thus exposure performance to some extent can be achieved.

FIG. 17 is a flowchart illustrating processing of setting the start voltage Vs and the end voltage Ve in the first embodiment. The laser control processor 130 calculates the start voltage Vs and the end voltage Ve based on the integration spectrum central wavelength λ0 and the wavelength range Δλ as described below.

At S1, the laser control processor 130 receives data of the integration spectrum central wavelength λ0 and the wavelength range Δλ from the exposure control processor 210.

At S2, the laser control processor 130 calculates the start wavelength λs and the end wavelength λe by expressions below.

λs=λ0−Δλ/2

λe=λ0+Δλ/2

At S3, the laser control processor 130 reads a relational expression λ=f(0) of the wavelength λ and the rotation angles θ1 and θ2 from the memory 132 and calculates a start rotation angle θs and an end rotation angle θe corresponding to the start wavelength λs and the end wavelength λe. The start rotation angle θs and the end rotation angle θe are the same for the rotation angles θ1 and θ2.

At S4, the laser control processor 130 reads a relational expression θ=g(V) of the rotation angles θ1 and θ2 and the drive voltages V1 and V2 from the memory 132 and calculates the start voltage Vs and the end voltage Ve corresponding to the start rotation angle θs and the end rotation angle θe. The start voltage Vs and the end voltage Ve are the same for the drive voltages V1 and V2.

After the calculation of the start voltage Vs and the end voltage Ve, the drive voltages V1 and V2 in opposite phases are applied to the rotation stages 161 and 162 in the variation period 2N/F, so that the integration spectrum waveform can have a flat-top shape.

After S4, the laser control processor 130 ends the processing of the present flowchart.

Although the above description is made on a case in which the rotation stages 161 and 162 change the rotation angles θ1 and θ2 of the first and second mirrors 61 and 62 in accordance with the drive voltages V1 and V2, the present disclosure is not limited thereto. The rotation stages 161 and 162 may include stepping motors to change the rotation angles θ1 and θ2 of the first and second mirrors 61 and 62 in accordance with the number of counts of control pulses.

### 2.3 Effect

(1) According to the first embodiment, the laser apparatus 100a includes the grating 53, the actuator system 160, and the laser control processor 130. The actuator system 160 adjusts the first incident angle α1 of the first part 91 on the grating 53 and the second incident angle α2 of the second part 92 on the grating 53, the first part 91 being a part of the optical beam 90 incident on the grating 53, the second part 92 being another part of the optical beam 90. The laser control processor 130 controls the actuator system 160 to periodically vary the first and second incident angles α1 and α2 so that the first and second incident angles α1 and α2 are different from each other in phase.

With this configuration, the first and second incident angles α1 and θ2 gradually vary. Accordingly, operation of the actuator system 160 can follow a control signal, and the integration spectrum waveform closer to an ideal waveform can be obtained.

(2) According to the first embodiment, the laser apparatus 100a includes the first mirror 61 disposed on the optical path of the first part 91, and the second mirror 62 disposed on the optical path of the second part 92.

With this configuration, the first and second incident angles α1 and α2 can be adjusted by using the first and second mirrors 61 and 62.

(3) According to the first embodiment, the laser apparatus 100a includes the laser chamber 10 that outputs the optical beam 90, and the prisms 41 to 43 that increase the beam width of the optical beam 90 so that the optical beam 90 is incident across the first and second mirrors 61 and 62.

With this configuration, the first and second incident angles α1 and α2 can be adjusted without bifurcating the optical beam 90.

(4) According to the first embodiment, the actuator system 160 includes the rotation stage 161 configured to vary the first incident angle α1, and the rotation stage 162 configured to vary the second incident angle α2.

With this configuration, the first and second incident angles α1 and θ2 can be independently varied.

(5) According to the first embodiment, the laser control processor 130 varies the first and second incident angles α1 and α2 so that the first and second incident angles α1 and α2 have a phase difference of 7π/8 radian to 9π/8 radian inclusive.

With this configuration, since the phases of the first and second incident angles α1 and α2 are substantially opposite to each other, the integration spectrum waveform in the half period N/F has a flat-top shape. Moreover, since the first and second mirrors 61 and 62 rotate in directions opposite to each other, the total angular momentum of the first and second mirrors 61 and 62 is stable at a small value. Accordingly, the apparatus has small mechanical vibration as a whole and can perform stable wavelength control.

(6) According to the first embodiment, the laser control processor 130 varies the first and second incident angles α1 and α2 so that the first and second incident angles α1 and α2 have variation ranges equal to each other.

With this configuration, load concentration on one actuator can be suppressed.

(7) According to the first embodiment, the laser control processor 130 varies the first and second incident angles α1 and α2 in the variation period 2N/F obtained by multiplying the pulse repetition period 1/F of the pulse laser beam output from the laser apparatus 100a by twice of the number N of irradiation pulses of the pulse laser beam with which one place of the irradiation target object is irradiated.

With this configuration, since the first and second incident angles α1 and θ2 are varied in the variation period 2N/F, which is equal to twice of the required time T for the scanning field SF to move a distance equivalent to the width W of the beam section B of the pulse laser beam, the variation of the first and second incident angles α1 and α2 is gradual.

Any other feature of the first embodiment is the same as that of the comparative example.

### 3. Laser Apparatus 100a with Mutually Different Variation Ranges of First and Second Incident Angles α1 and α2

### 3.1 Configuration and Operation

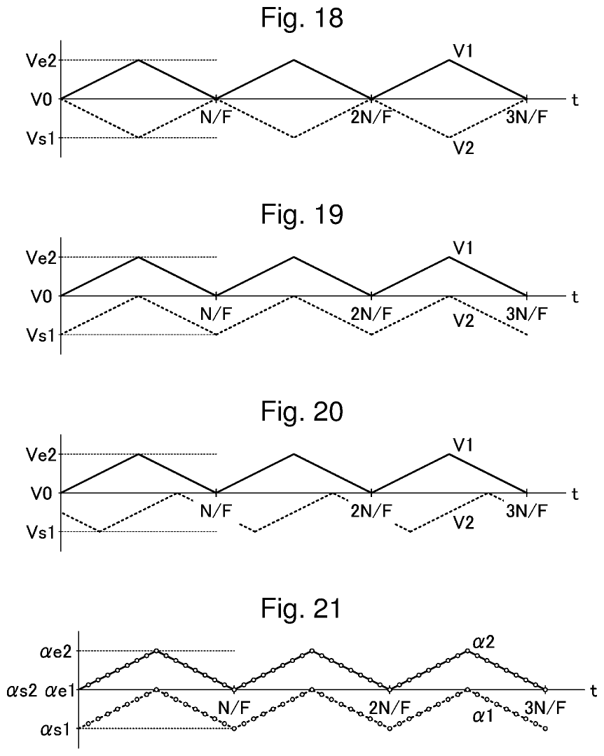

FIGS. 18 to 20 are graphs illustrating examples of the drive voltages V1 and V2 applied to the rotation stages 161 and 162 in a second embodiment. In FIGS. 18 to 20, the horizontal axis represents time t, and the vertical axis represents the drive voltages V1 and V2. The configuration of the second embodiment is the same as the configuration of the first embodiment described above with reference to FIG. 12. The drive voltages V1 and V2 in the second embodiment have characteristics as follows.
(a) The drive voltages V1 and V2 periodically vary in variation ranges different from each other.
(b) The drive voltages V1 and V2 each vary in a variation period equal to the time N/F obtained by multiplying the repetition period 1/F of the pulse laser beam by the number N of irradiation pulses.
(c) The drive voltages V1 and V2 may have identical phases, opposite phases, or another phase difference.

FIG. 18 illustrates a case in which the drive voltages V1 and V2 have opposite phases. FIG. 19 illustrates a case in which the drive voltages V1 and V2 have identical phases. FIG. 20 illustrates a case in which the drive voltages V1 and V2 do not have identical nor opposite phases but have another phase difference. In any of FIGS. 18 to 20, the integration spectrum waveform in one period N/F is a flat-top spectrum waveform.

FIG. 21 is a graph illustrating an example of the first incident angle α1 of the first part 91 and the second incident angle α2 of the second part 92 that are incident on the grating 53 in the second embodiment. In FIG. 21, the horizontal axis represents time t, and the vertical axis represents the first and second incident angles α1 and α2. Each small circle illustrated in FIG. 21 represents an output timing of the pulse laser beam and the first and second incident angles α1 and α2 at the timing.

As illustrated in FIG. 21, the first incident angle α1 of the first part 91 has a variation range of a first start incident angle αs1 to a first end incident angle αe1 larger than the first start incident angle αs1. The second incident angle α2 of the second part 92 has a variation range of a second start incident angle αs2 larger than the first start incident angle αs1 to a second end incident angle αe2 larger than the second start incident angle αs2. The first start incident angle αs1 corresponds to a first value in the present disclosure, the first end incident angle αe1 corresponds to a second value in the present disclosure, the second start incident angle αs2 corresponds to a third value in the present disclosure, and the second end incident angle αe2 corresponds to a fourth value in the present disclosure.

The second start incident angle αs2 is preferably equal to or larger than the first end incident angle αe1.

Although FIG. 21 illustrates a case in which the first and second incident angles α1 and α2 have identical phases, the present disclosure is not limited to the case. As described above with reference to FIGS. 18 to 20, the first and second incident angles α1 and α2 may have identical phases, opposite phases, or another phase difference.

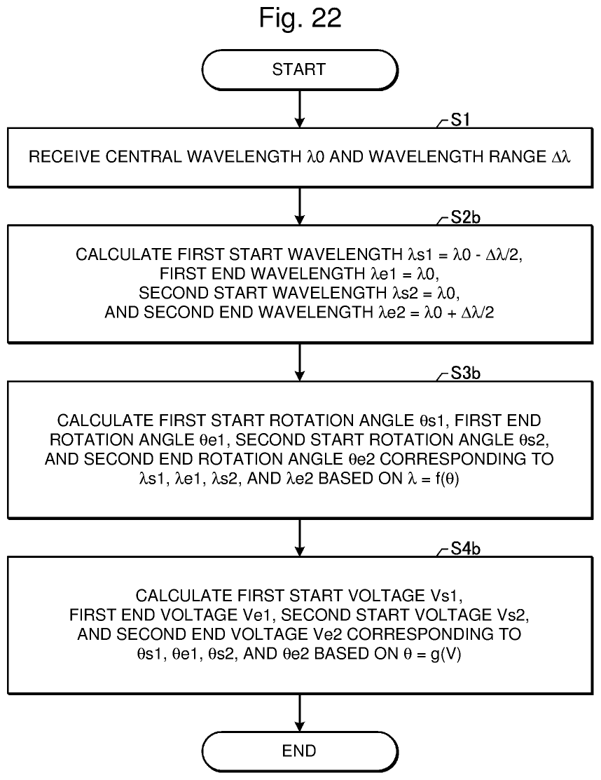

FIG. 22 is a flowchart illustrating processing of setting a first start voltage Vs1, a first end voltage Ve1, a second start voltage Vs2, and a second end voltage Ve2 in the second embodiment. The first start voltage Vs1, the first end voltage Ve1, the second start voltage Vs2, and the second end voltage Ve2 correspond to the first start incident angle αs1, the first end incident angle αe1, the second start incident angle αs2, and the second end incident angle αe2, respectively.

Processing at S1 is the same as described above with reference to FIG. 17.

At S2b, the laser control processor 130 calculates a first start wavelength λs1, a first end wavelength λe1, a second start wavelength λs2, and a second end wavelength λe2 corresponding to the first start incident angle αs1, the first end incident angle αe1, the second start incident angle αs2, and the second end incident angle αe2, respectively, by expressions below.

λs1=λ0−Δλ/2

λe1=λ0

λs2=λ0

λe2=λ0+Δλ/2

At S3b, the laser control processor 130 calculates a first start rotation angle θs1, a first end rotation angle θe1, a second start rotation angle θs2, and a second end rotation angle θe2 corresponding to the first start wavelength λs1, the first end wavelength λe1, the second start wavelength λs2, and the second end wavelength λe2, respectively.

At S4b, the laser control processor 130 calculates the first start voltage Vs1, the first end voltage Ve1, the second start voltage Vs2, and the second end voltage Ve2 corresponding to the first start rotation angle θs1, the first end rotation angle θe1, the second start rotation angle θs2, and the second end rotation angle θe2, respectively.

Any other feature of the processing illustrated in FIG. 22 is the same as that of the processing illustrated in FIG. 17.

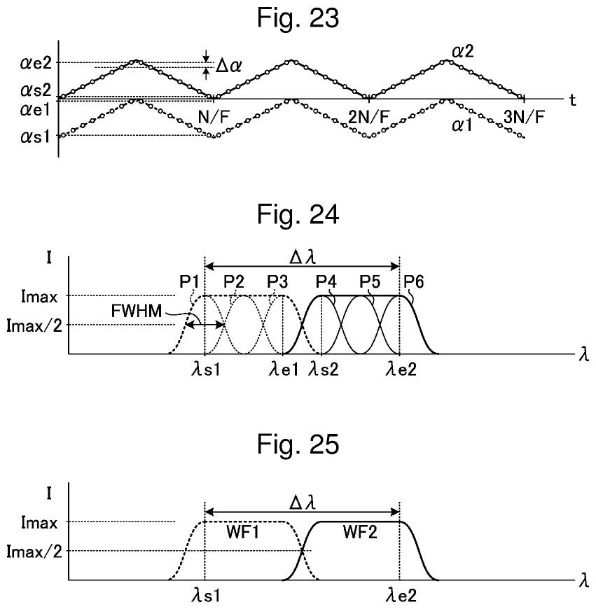

FIG. 23 is a graph illustrating a modification of the first and second incident angles α1 and α2 in the second embodiment. In FIG. 23, the horizontal axis represents time t, and the vertical axis represents the first and second incident angles α1 and α2. Each small circle illustrated in FIG. 23 represents an output timing of the pulse laser beam and the first and second incident angles α1 and α2 at the timing.

As illustrated in FIG. 23, the second start incident angle αs2 may be larger than the first end incident angle αe1. The difference αs2−αe1 between the second start incident angle αs2 and the first end incident angle θe1 is preferably equal to or smaller than a variation width Δα of the first or second incident angle α1 or α2 per pulse.

As illustrated in FIGS. 21 and 23, the difference αe1−αs1 between the first start incident angle αs1 and the first end incident angle αe1 is preferably equal to the difference αe2−αs2 between the second start incident angle αs2 and the second end incident angle αe2.

FIG. 24 illustrates an example of the integration spectrum waveform in one period N/F in the second embodiment. The horizontal axis represents the wavelength λ, and the vertical axis represents the light intensity I. FIG. 24 also illustrates spectrum waveforms of pulses P1 to P6 included in one period N/F. The pulses P1 to P3 are included in the first part 91, and the pulses P4 to P6 are included in the second part 92.

The first end wavelength λe1 corresponds to a first pulse spectrum central wavelength of the selection wavelength when the first incident angle α1 is the first end incident angle αe1, and the second start wavelength λs2 corresponds to a second pulse spectrum central wavelength of the selection wavelength when the second incident angle α2 is the second start incident angle αs2. The second start wavelength λs2 may be larger than the first end wavelength λe1. In other words, the second start incident angle αs2 may be larger than the first end incident angle αe1. The difference λs2−λe1 between the first end wavelength λe1 and the second start wavelength λs2 is preferably equal to the full width at half maximum FWHM of the pulse spectrum waveform of any of the pulses P1 to P6.

FIG. 25 illustrates a modification of the integration spectrum waveform in one period N/F in the second embodiment. The horizontal axis represents the wavelength λ, and the vertical axis represents the light intensity I. A first integration spectrum waveform WF1 is the integration spectrum waveform when the first incident angle α1 is periodically varied, and a second integration spectrum waveform WF2 is the integration spectrum waveform when the second incident angle α2 is periodically varied. The first integration spectrum waveform WF1 and the second integration spectrum waveform WF2 have a peak intensity Imax.

The first integration spectrum waveform WF1 and the second integration spectrum waveform WF2 preferably intersect each other at their half maximum Imax/2.

### 3.2 Effect

(8) According to the second embodiment, the first incident angle α1 has a variation range of the first start incident angle αs1 to the first end incident angle αe1 larger than the first start incident angle αs1, and the second incident angle α2 has a variation range of the second start incident angle αs2 larger than the first start incident angle αs1 to the second end incident angle αe2 larger than the second start incident angle αs2.

With this configuration, since the variation ranges of the first and second incident angles α1 and α2 are set to be different from each other, the first and second incident angles α1 and θ2 gradually vary. Accordingly, operation of the actuator system 160 can follow a control signal, and the integration spectrum waveform closer to an ideal waveform can be obtained.

(9) According to the second embodiment, the second start incident angle αs2 is equal to or larger than the first end incident angle αe1.

With this configuration, since overlapping of the variation ranges of the first and second incident angles α1 and α2 is reduced, the first and second incident angles α1 and α2 gradually vary.

(10) According to the second embodiment, the difference αs2−αe1 between the first end incident angle αe1 and the second start incident angle αs2 is equal to or smaller than the variation width Δα of any of the first and second incident angles α1 and α2 of the pulse laser beam output from the laser apparatus 100a per pulse.

With this configuration, the integration spectrum waveform can have a flat-top shape.

(11) According to the second embodiment, the difference λe1−αs1 between the first start incident angle αs1 and the first end incident angle αe1 is equal to the difference αe2−αs2 between the second start incident angle αs2 and the second end incident angle αe2.

With this configuration, since the variation widths of the first and second incident angles α1 and α2 are equal to each other, load concentration on one actuator can be suppressed.

(12) According to the second embodiment, the difference λs2−λe1 between the first end wavelength λe1 when the first incident angle α1 is the first end incident angle αe1 and the second start wavelength λs2 when the second incident angle α2 is the second start incident angle αs2 is equal to the full width at half maximum FWHM of the pulse spectrum waveform of any of the first and second parts 91 and 92.

With this configuration, the integration spectrum waveform can be made closer to a flat-top shape.

(13) According to the second embodiment, the first integration spectrum waveform WF1 when the first incident angle α1 is periodically varied and the second integration spectrum waveform WF2 when the second incident angle α2 is periodically varied intersect each other at their half maximum Imax/2.

With this configuration, the entire integration spectrum waveform of the first and second integration spectrum waveforms WF1 and WF2 can be made closer to a flat-top shape.

Any other feature of the second embodiment is the same as that of the first embodiment.

### 4. Laser Apparatus 100c that Adjusts First and Second Incident Angles α1 and α2 by Adjusting Rotation Angles θ1 and θ2 of Prisms 44 and 45

### 4.1 Configuration and Operation

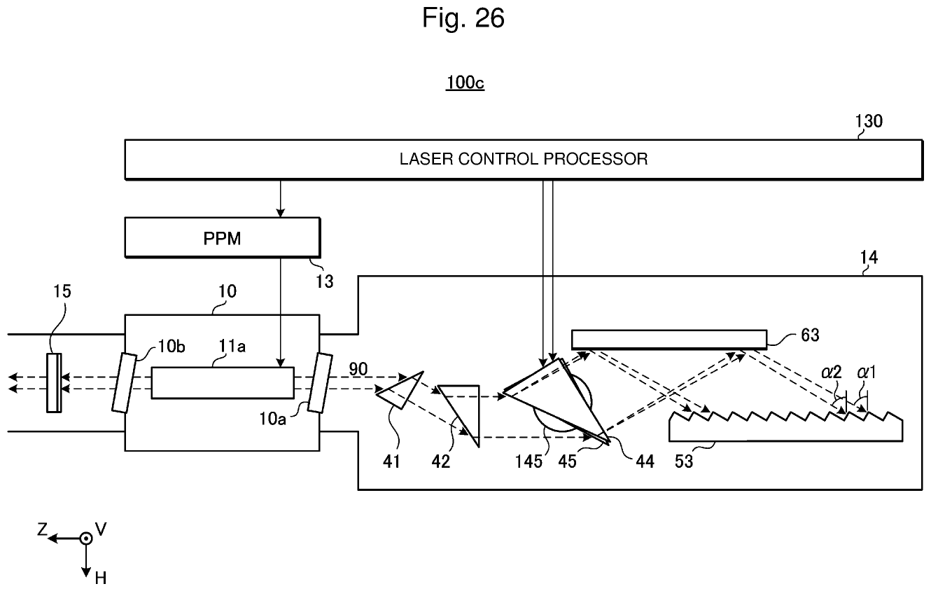

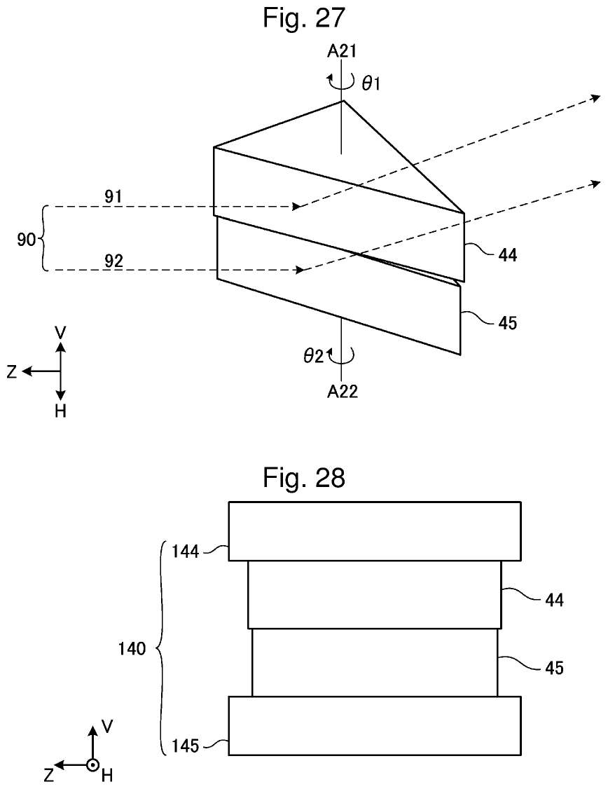

FIG. 26 schematically illustrates the configuration of a laser apparatus 100c according to a third embodiment. FIG. 26 corresponds to a view of the laser apparatus 100c in the same direction as in FIG. 2 in the comparative example. The laser apparatus 100c includes prisms 44 and 45 in place of the prism 43 illustrated in FIG. 2. FIG. 27 is a perspective view of the prisms 44 and 45. FIG. 28 is a side view of the prisms 44 and 45. FIG. 27 corresponds to a view of the prisms 44 and 45 in a direction parallel to a VH plane, and FIG. 28 corresponds to a view of the prisms 44 and 45 in the negative H axial direction. The prisms 44 and 45 correspond to first and second prisms in the present disclosure.

The prisms 44 and 45 are disposed side by side in a direction parallel to the V axis. The prisms 44 and 45 are disposed such that surfaces of the prisms 44 and 45 to and from which the optical beam 90 is input and output are parallel to the V axis. The prisms 44 and 45 are independently rotatable about axes A21 and A22 parallel to the V axis by rotation stages 144 and 145, respectively. The rotation stages 144 and 145 constituting an actuator system 140 correspond to the first and second actuators, respectively.

The prisms 44 and 45 are disposed such that the optical beam 90 output from the laser chamber 10 and having transmitted through the prisms 41 and 42 is incident across the prisms 44 and 45. One of the prisms 41 and 42 corresponds to a third prism in the present disclosure. In the optical beam 90, a part incident on the prism 44 is the first part 91, and a part incident on the prism 45 is the second part 92. The first and second parts 91 and 92 transmit through the prisms 44 and 45, respectively, and are reflected by the mirror 63 and incident on the grating 53.

The rotation angles θ1 and θ2 of the prisms 44 and 45 change in accordance with the drive voltages V1 and V2 applied to the rotation stages 144 and 145, respectively, and the directions of refraction of the first and second parts 91 and 92 by the prisms 44 and 45 change, respectively. Accordingly, the first incident angle α1 of the first part 91 and the second incident angle α2 of the second part 92 that are incident on the grating 53 change.

### 4.2 Effect

(14) According to the third embodiment, the laser apparatus 100c includes the prism 44 disposed on the optical path of the first part 91, and the prism 45 disposed on the optical path of the second part 92.

With this configuration, the first and second incident angles α1 and α2 can be adjusted by using the prisms 44 and 45.

(15) According to the third embodiment, the laser apparatus 100c includes the laser chamber 10 that outputs the optical beam 90, and the prisms 41 and 42 that increase the beam width of the optical beam 90 so that the optical beam 90 is incident across the prisms 44 and 45.

With this configuration, the first and second incident angles α1 and α2 can be adjusted without bifurcating the optical beam 90.

Any other feature of the third embodiment is the same as that of the first or second embodiment.

### 5. Laser Apparatus 100d that Adjusts First and Second Incident Angles α1 and α2 by Adjusting Rotation Angles θ1 and θ2 of First and Second Gratings 51 and 52

### 5.1 Configuration and Operation

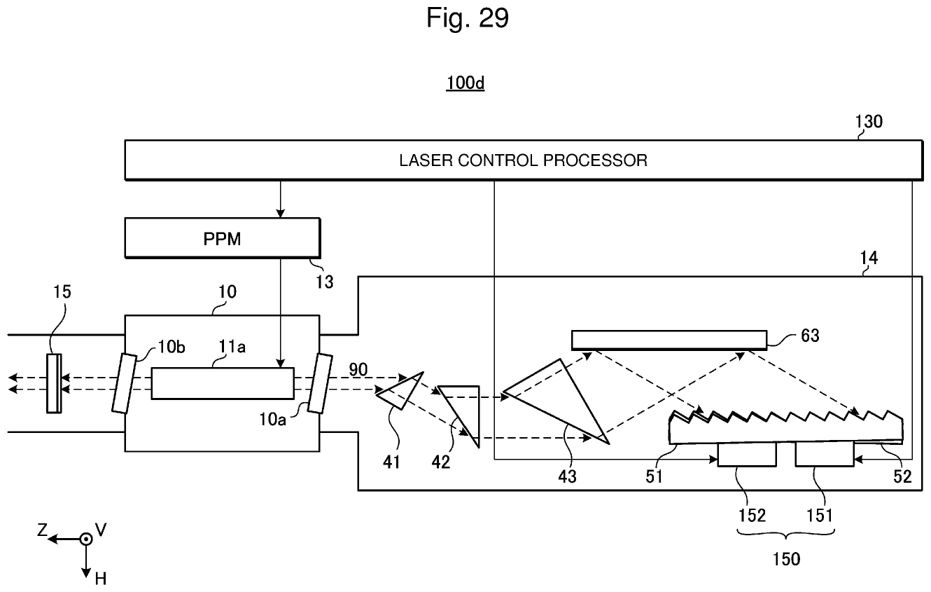

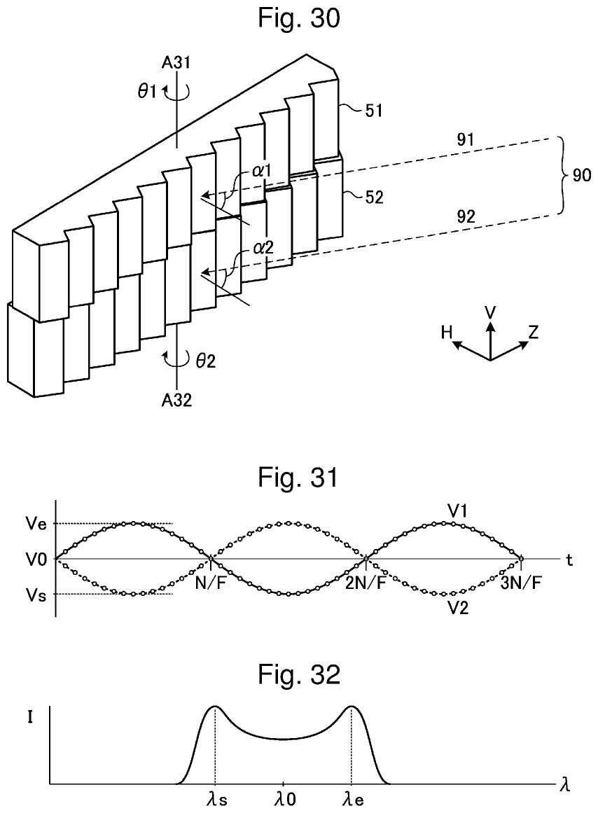

FIG. 29 schematically illustrates the configuration of a laser apparatus 100d according to a fourth embodiment. FIG. 29 corresponds to a view of the laser apparatus 100d in the same direction as in FIG. 2 in the comparative example. The laser apparatus 100d includes first and second gratings 51 and 52 in place of the grating 53 illustrated in FIG. 2. FIG. 30 is a perspective view of the first and second gratings 51 and 52. The first and second gratings 51 and 52 are an example of the grating system in the present disclosure.

The first and second gratings 51 and 52 are disposed side by side in a direction parallel to the V axis. The first and second gratings 51 and 52 are disposed such that the direction of grooves of each of the first and second gratings 51 and 52 is parallel to the V axis. The first and second gratings 51 and 52 are independently rotatable about axes A31 and A32 parallel to the V axis by rotation stages 151 and 152, respectively. The rotation stages 151 and 152 constituting an actuator system 150 correspond to the first and second actuators, respectively.

The optical beam 90 output from the laser chamber 10 transmits through the prisms 41 to 43 and is reflected by the mirror 63 and incident across the first and second gratings 51 and 52. In the optical beam 90, a part incident on the first grating 51 is the first part 91, and a part incident on the second grating 52 is the second part 92.

The rotation angles θ1 and θ2 of the first and second gratings 51 and 52 change in accordance with the drive voltages V1 and V2 applied to the rotation stages 151 and 152, respectively. Accordingly, the first incident angle α1 of the first part 91 incident on the first grating 51 and the second incident angle α2 of the second part 92 incident on the second grating 52 change.

### 5.2 Effect

(16) According to the fourth embodiment, the laser apparatus 100d includes, as the grating system, the first grating 51 disposed on the optical path of the first part 91, and the second grating 52 disposed on the optical path of the second part 92.

With this configuration, the first and second incident angles α1 and α2 can be adjusted by using the first and second gratings 51 and 52.

(17) According to the fourth embodiment, the laser apparatus 100d includes the laser chamber 10 that outputs the optical beam 90, and the prisms 41 to 43 that increase the beam width of the optical beam 90 so that the optical beam 90 is incident across the first and second gratings 51 and 52.

With this configuration, the first and second incident angles α1 and α2 can be adjusted without bifurcating the optical beam 90.

(18) According to the first to fourth embodiments, the laser control processor 130 varies each of the first and second incident angles α1 and θ2 in a triangular wave shape.

With this configuration, the variation width Δα of the first and second incident angles α1 and α2 is substantially constant, and thus the integration spectrum waveform can have a flat-top shape.

Any other feature of the fourth embodiment is the same as that of the first or second embodiment.

### 6. Laser Apparatus 100a that Varies First and Second Incident Angles α1 and θ2 in Sinusoidal Shape

### 6.1 Configuration and Operation

Although each of the first and second incident angles α1 and θ2 is varied in a triangular wave shape in the above-described embodiments, the present disclosure is not limited thereto. Each of the first and second incident angles α1 and θ2 may be varied in a sinusoidal shape.

FIG. 31 is a graph illustrating an example of the drive voltages V1 and V2 applied to the rotation stages 161 and 162 (refer to FIG. 12) in a fifth embodiment. In FIG. 31, the horizontal axis represents time t, and the vertical axis represents the drive voltages V1 and V2.

FIG. 32 illustrates the integration spectrum waveform in the half period N/F when the drive voltages V1 and V2 illustrated in FIG. 31 are applied to the rotation stages 161 and 162. In FIG. 32, the horizontal axis represents the wavelength λ, and the vertical axis represents the light intensity I. In the fifth embodiment, since the first and second incident angles α1 and θ2 are varied in a sinusoidal shape by varying the drive voltages V1 and V2 in a sinusoidal shape, the light intensity I of the integration spectrum waveform is higher near the start wavelength λs and the end wavelength λe.

### 6.2 Effect

(19) According to the fifth embodiment, the laser control processor 130 varies each of the first and second incident angles α1 and α2 in a sinusoidal shape.

With this configuration, abrupt change in the angular velocities of the first and second mirrors 61 and 62 is suppressed, and operation of the actuator system 160 can follow a control signal.

Any other feature of the fifth embodiment is the same as that of the first embodiment.

Alternatively, in the second to fourth embodiments, the first and second incident angles α1 and α2 may be varied in a sinusoidal shape by varying the drive voltages V1 and V2 in a sinusoidal shape.

### 7. Other

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a grating system;
an actuator system configured to adjust a first incident angle on the grating system and a second incident angle on the grating system, the first incident angle being an angle of a first part of an optical beam incident on the grating system, the second incident angle being an angle of a second part of the optical beam incident on the grating system; and
a processor configured to control the actuator system to periodically vary the first and second incident angles so that the first and second incident angles are different from each other in at least one of phase and variation range.

2. The laser apparatus according to claim 1, further comprising:
a first mirror disposed on an optical path of the first part; and
a second mirror disposed on an optical path of the second part.

3. The laser apparatus according to claim 2, further comprising:
a laser chamber that outputs the optical beam; and
at least one prism that increases a beam width of the optical beam so that the optical beam is incident across the first and second mirrors.

4. The laser apparatus according to claim 1, wherein the actuator system includes
a first actuator configured to vary the first incident angle, and
a second actuator configured to vary the second incident angle.

5. The laser apparatus according to claim 4, wherein the processor varies the first and second incident angles so that the first and second incident angles have a phase difference of 7π/8 radian to 9π/8 radian inclusive.

6. The laser apparatus according to claim 5, wherein the processor varies the first and second incident angles so that the first and second incident angles have variation ranges equal to each other.

7. The laser apparatus according to claim 5, wherein the processor varies the first and second incident angles in a variation period obtained by multiplying a pulse repetition period of a pulse laser beam output from the laser apparatus by twice of a number of irradiation pulses of the pulse laser beam with which one place of an irradiation target object is irradiated.

8. The laser apparatus according to claim 1, wherein the processor varies the first and second incident angles so that
the first incident angle has a variation range of a first value to a second value larger than the first value, and
the second incident angle has a variation range of a third value larger than the first value to a fourth value larger than the third value.

9. The laser apparatus according to claim 8, wherein the third value is equal to or larger than the second value.

10. The laser apparatus according to claim 9, wherein a difference between the second value and the third value is equal to or smaller than a variation width of any of the first and second incident angles per pulse of a pulse laser beam output from the laser apparatus.

11. The laser apparatus according to claim 8, wherein a difference between the first value and the second value is equal to a difference between the third value and the fourth value.

12. The laser apparatus according to claim 8, wherein a difference between a first pulse spectrum central wavelength when the first incident angle is the second value and a second pulse spectrum central wavelength when the second incident angle is the third value is equal to a full width at half maximum of a pulse spectrum waveform of any of the first and second parts.

13. The laser apparatus according to claim 8, wherein a first integration spectrum waveform when the first incident angle is periodically varied and a second integration spectrum waveform when the second incident angle is periodically varied intersect each other at a half maximum of the integration spectrum waveforms.

14. The laser apparatus according to claim 1, further comprising:
a first prism disposed on an optical path of the first part; and
a second prism disposed on an optical path of the second part.

15. The laser apparatus according to claim 14, further comprising:
a laser chamber that outputs the optical beam; and
a third prism that increases a beam width of the optical beam so that the optical beam is incident across the first and second prisms.

16. The laser apparatus according to claim 1, wherein the grating system includes
a first grating disposed on an optical path of the first part, and
a second grating disposed on an optical path of the second part.

17. The laser apparatus according to claim 16, further comprising:
a laser chamber that outputs the optical beam; and
at least one prism that increases a beam width of the optical beam so that the optical beam is incident across the first and second gratings.

18. The laser apparatus according to claim 1, wherein the processor varies each of the first and second incident angles in a triangular wave shape.

19. The laser apparatus according to claim 1, wherein the processor varies each of the first and second incident angles in a sinusoidal shape.

20. A method of manufacturing an electronic device, the method comprising:
generating a laser beam with a laser apparatus, the laser apparatus including
a grating system,
an actuator system configured to adjust a first incident angle on the grating system and a second incident angle on the grating system, the first incident angle being an angle of a first part of an optical beam incident on the grating system, the second incident angle being an angle of a second part of the optical beam incident on the grating system, and
a processor configured to control the actuator system to periodically vary the first and second incident angles so that the first and second incident angles are different from each other in at least one of phase and variation range;
outputting the laser beam to an exposure apparatus; and
exposing a photosensitive substrate to the laser beam in the exposure apparatus to manufacture the electronic device.
